(19) United States
(12) Patent Application Publication
(10) Pub. No.: US 2026/0130166 A1
(43) Pub. Date: May 7, 2026

(54) AUTOMATIC CARRIER SLOT SCANNING APPARATUS FOR GLASS SUBSTRATE SEMICONDUCTOR PACKAGE

(71) Applicant: Absolics Inc., Covington, GA (US)

(72) Inventors: Sangmin YUN, Covington, GA (US); Younjune KIM, Covington, GA (US); Jieun KIM, Covington, GA (US)

(73) Assignee: Absolics Inc., Covington, GA (US)

(21) Appl. No.: 19/379,756

(22) Filed: Nov. 5, 2025

Related U.S. Application Data
(60) Provisional application No. 63/716,242, filed on Nov. 5, 2024.

(51) Int. Cl. H01L 21/67; H01L 21/677

(52) U.S. Cl. CPC H10P 72/0608; H10P 72/0618; H10P 72/3404

(57) ABSTRACT

An embodiment relates to an automatic carrier slot scanning apparatus for glass substrate semiconductor packages for automation of a glass substrate semiconductor package factory, and more particularly, to an automatic carrier slot scanning apparatus for glass substrate semiconductor packages configured to automatically scan positions and the number of glass substrates for slots of a carrier, compare the scanned information with related information of a manufacturing execution system, and thereby achieve synchronization.

### CROSS-REFERENCE TO RELATED APPLICATION

This application claims priority of U.S. Provisional Patent Application No. 63/716,242, filed on November 05, 2024, the entire disclosure of which is hereby incorporated by reference for all purposes.

### BACKGROUND

### 1. Field of the Invention

An embodiment relates to an automatic carrier slot scanning apparatus for glass substrate semiconductor packages to automate a glass substrate semiconductor package factory.

### 2. Discussion of Related Art

Recently, in order to replace plastic substrates used in a semiconductor packaging field, glass substrates made of glass have been developed and are being used. Such glass substrates are regarded as innovative substrate materials that may change the landscape of the semiconductor packaging field.

That is, the glass substrate has a smooth surface and excellent processability into large quadrangular panels and is thus suitable for implementing semiconductor packaging with ultra-fine line widths. In addition, since no intermediate substrate is required, a thickness of the substrate can be reduced, and power consumption can also be reduced.

Here, in a glass substrate semiconductor package factory, the glass substrates are grouped into lots, each of which has a predetermined number of glass substrates, and are individually loaded into a plurality of slots provided at regular intervals inside a carrier (cassette).

That is, the glass substrates are transported by transport equipment after being loaded into the slots of the carrier, withdrawn from the slots of the carrier by transfer equipment according to a processing sequence, loaded into process equipment to be processed, and then reloaded into the slots of the carrier.

Meanwhile, in order to operate the glass substrate semiconductor package factory in an automated manner, it is necessary to accurately identify the positions and number of the glass substrates for each slot of the carrier.

That is, it is necessary to accurately determine which slot of the carrier the glass substrate is located in and how many glass substrates are loaded in the slots of the carrier, so that the information matches slot information of a manufacturing execution system (MES, e.g., a workflow service (WFS)), thereby enabling the glass substrate semiconductor package factory to be operated in an automated manner.

However, in the current glass substrate semiconductor package factory, all inventory sorting operations for checking the positions and number of glass substrates for each slot of the carrier are performed manually, making it difficult to accurately synchronize with the slot information of the manufacturing execution system.

Accordingly, research is required on a technology for automatically scanning the positions and number of glass substrates for each slot of the carrier and comparing the scanned information with the slot information of the manufacturing execution system so that synchronization is achieved.

The aforementioned background technology is technical information possessed by the inventor for derivation of the present invention or acquired by the inventor during the derivation of the present invention and is not necessarily the related art disclosed to the public before the application of the present invention.

Related art references include Korean Laid-Open Patent Publication No. 10-2005-0067603, published on July 5, 2005, Korean Laid-Open Patent Publication No. 10-2008-0024375, published on March 18, 2008, and Korean Registered Patent Publication No. 10-0828972, registered on May 13, 2008.

### SUMMARY OF THE INVENTION

An embodiment has been made to solve the above-described problems, and an object thereof is to provide an automatic carrier slot scanning apparatus for glass substrate semiconductor packages, which automatically scans the positions and number of glass substrates for each slot of a carrier, compares scanned information with slot information of a manufacturing execution system to achieve synchronization, and enables a glass substrate semiconductor package factory to be operated in an automated manner.

The objectives of the present invention are not limited to the above-mentioned objective, and other objectives which are not mentioned above will be clearly understood from the following description and are sufficiently included in the objective of the present invention.

According to an aspect of the present disclosure, there is provided an automatic carrier slot scanning apparatus for glass substrate semiconductor packages, which scans positions and the number of glass substrates allocated on a lot basis for each slot of carriers that are handled in a glass substrate semiconductor package factory and each of which has an identification code attached thereto, and compares scanned information with slot information of a manufacturing execution system, the automatic carrier slot scanning apparatus including a list generation unit configured to generate a list of carriers stored in each stocker, a scan task preparation unit configured to search for process equipment, which allows a scan task to be performed, and prepare the scan task, a scan task execution unit configured to select any one carrier included in the list, load the selected carrier into the process equipment, and automatically scan positions and the number of glass substrates for each slot of the carrier, a scan information comparison unit configured to compare scan information, which is output according to the automatic scanning and corresponds to the positions and the number of glass substrates for the slots of the carrier, with slot information previously stored in the manufacturing execution system, and to determine whether the scan information matches the slot information, and an error occurrence notification unit configured to, when the scan information does not match the slot information based on a result of determining whether the scan information matches the slot information, set the carrier to a holding state, store the carrier in the stocker, and transmit an error occurrence signal to an administrator terminal.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a block diagram illustrating an automatic carrier slot scanning apparatus for glass substrate semiconductor packages according to an exemplary embodiment of the present disclosure; and

FIG. 2 is a configuration diagram illustrating a control server for operating the automatic carrier slot scanning apparatus for glass substrate semiconductor packages according to the exemplary embodiment of the present disclosure.

### DETAILED DESCRIPTION OF EXEMPLARY EMBODIMENTS

Embodiments relate to an automatic carrier slot scanning apparatus for glass substrate semiconductor packages to automate a glass substrate semiconductor package factory.

In particular, the automatic carrier slot scanning apparatus for glass substrate semiconductor packages according to the embodiment automatically scans the positions and number of glass substrates for each slot of a carrier and compares scanned information with slot information of a manufacturing execution system (MES) so that synchronization is achieved.

Hereinafter, the automatic carrier slot scanning apparatus for glass substrate semiconductor packages according to exemplary embodiments of the present disclosure will be described in detail with reference to the accompanying drawings.

An automatic carrier slot scanning apparatus 100 for glass substrate semiconductor packages according to the exemplary embodiment of the present disclosure is configured to automatically scan the positions and number of glass substrates transported while stored in each carrier (cassette) stored in a stocker, compare scanned information with slot information previously stored in an MES 400, determine presence or absence of an error based on a match result, and notify an administrator of the determination result.

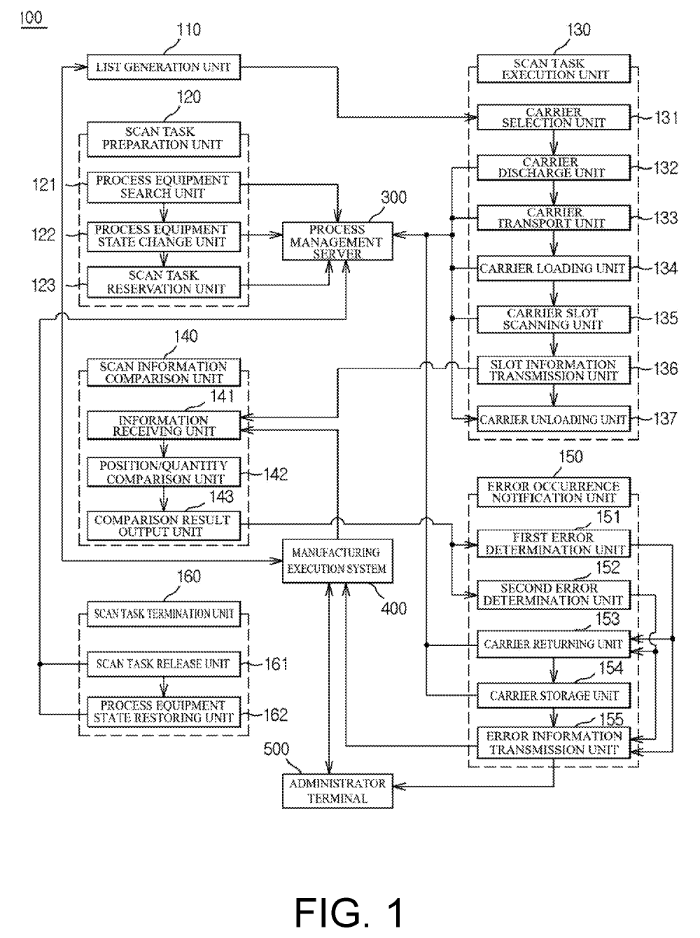

To this end, the automatic carrier slot scanning apparatus 100 for glass substrate semiconductor packages according to the exemplary embodiment of the present disclosure may include, as shown in FIG. 1, a list generation unit 110, a scan task preparation unit 120, a scan task execution unit 130, a scan information comparison unit 140, an error occurrence notification unit 150, and a scan task termination unit 160.

Each carrier may be provided with an identification code to distinguish the carrier from other carriers, a radio frequency identification (RFID) tag including identification information corresponding to the identification code may be attached to an outer side of each carrier, and each carrier may be registered in the manufacturing execution system 400 to be distinguished from each other through the identification code.

In addition, a plurality of slots may be provided inside each carrier to load and store a plurality of glass substrates in a positionally distinguishable manner, and a pair of optical sensors may be installed in each slot to automatically detect the presence or absence of the glass substrate and whether the glass substrate is broken by using infrared rays.

Further, each glass substrate may be assigned a unique number to distinguish the glass substrate from other glass substrates, each carrier may be allocated on the basis of lots of the glass substrates, and allocation information for the carriers may be previously stored in the manufacturing execution system 400. That is, the number of glass substrates stored in each carrier and the positions of the glass substrates for each slot of the carrier may be previously stored in the manufacturing execution system 400.

Meanwhile, the list generation unit 110, the scan task preparation unit 120, the scan task execution unit 130, the scan information comparison unit 140, the error occurrence notification unit 150, and the scan task termination unit 160 may be included in a control server 200 managed by an administrator.

In addition, the control server 200 may communicate with, via wired or wireless communication, a process management server 300 configured to control all processing processes and all process equipment of the glass substrate semiconductor package factory, the manufacturing execution system 400, a pre-designated administrator terminal 500, and the like, and may receive, transmit, and store related information.

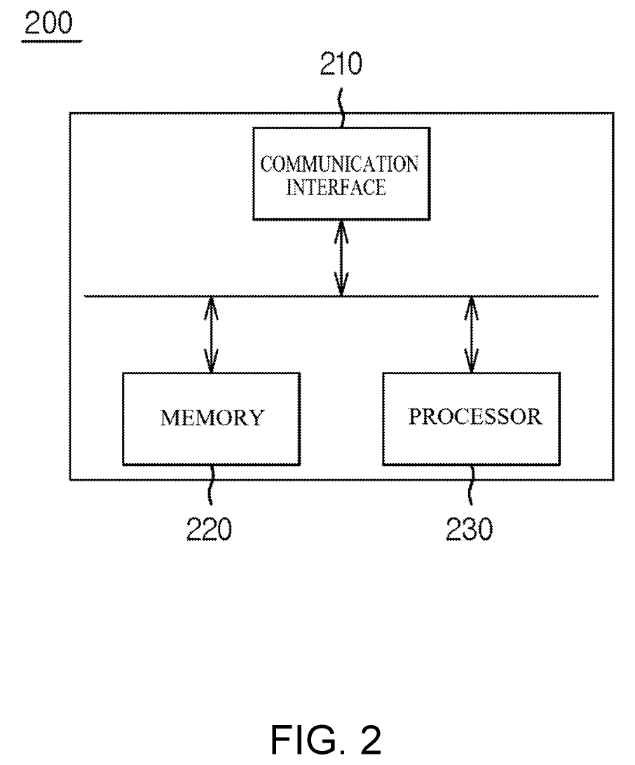

That is, as shown in FIG. 2, the control server 200 may include a communication interface 210, a memory 220, and a processor 230, the communication interface 210 performs communication with an external electronic device, receives a user input from the external electronic device, or provides data processing results to the administrator terminal, the memory 220 includes a computer-readable recording medium and stores an operating system and preset instructions, and the processor 230 performs processing operations such as interpretation of instructions, and computation and comparison of data.

First, the list generation unit 110 may generate and store a list of carriers stored in each stocker present within the glass substrate semiconductor package factory.

That is, the list generation unit 110 may generate a separate list for each stocker, and the lists separately generated for each stocker may be distinguished from each other through identification codes allocated to the respective carriers.

Next, the scan task preparation unit 120 may reserve a scan task in the process management server 300 so that the scan task can be performed using available process equipment (EQ) among process equipment present in the glass substrate semiconductor package factory.

To this end, as shown in FIG. 1, the scan task preparation unit 120 may include a process equipment search unit 121, a process equipment state change unit 122, and a scan task reservation unit 123.

The process equipment search unit 121 may search, through process management information stored in the process management server 300, whether there is process equipment currently in an available state among a plurality of pieces of process equipment present in the glass substrate semiconductor package factory.

In this case, the process equipment may include a sorter. That is, the process equipment search unit 121 may search for process equipment including the sorter that is currently in an available state.

The process equipment state change unit 122 may change the state of the process equipment, which has been found to currently be in an available state by the process equipment search unit 121, from the available state to an in-use state.

The scan task reservation unit 123 may reserve a scan task in the process management server 300 so that the scan task can be performed through the process equipment that has been changed to the in-use state by the process equipment state change unit 122.

Next, the scan task execution unit 130 may perform an automatic scan task for each slot of the carrier according to one of the lists generated by the list generation unit 110 by using the process equipment for which the scan task has been reserved by the scan task preparation unit 120.

To this end, as shown in FIG. 1, the scan task execution unit 130 may include a carrier selecting unit 131, a carrier discharge unit 132, a carrier transport unit 133, a carrier loading unit 134, a carrier slot scanning unit 135, a slot information transmission unit 136, and a carrier unloading unit 137.

The carrier selecting unit 131 may select any one carrier included in the list generated by the list generation unit 110.

In this case, when selecting a carrier to be a target of the scan task, the carrier selecting unit 131 may select the carrier in the order in which the carriers are written in the list, may arbitrarily select the carrier regardless of the order in which the carriers are written in the list, or may select the carrier based on a position where the carrier is stored in the stocker.

The carrier discharge unit 132 may discharge the carrier selected by the carrier selecting unit 131 from the stocker.

That is, the carrier discharge unit 132 may discharge the carrier from the stocker using a rack master provided in the stocker.

The carrier transport unit 133 may transport the carrier discharged from the stocker by the carrier discharge unit 132 to the process equipment through transport equipment.

The carrier loading unit 134 may load the carrier transported to the process equipment by the carrier transport unit 133 into transfer equipment (e.g., an equipment front end module (EFEM)) of the process equipment.

The carrier slot scanning unit 135 may perform a scan task for the slots of the carrier, which is loaded into the transfer equipment of the process equipment by the carrier loading unit 134, and may obtain scan information.

That is, the carrier slot scanning unit 135 may analyze slot images obtained through a camera mounted on the transfer equipment of the process equipment to obtain scan information including the number of glass substrates loaded into each slot and positions of the glass substrates based on positions of the slots into which the glass substrates are loaded.

The slot information transmission unit 136 may transmit the scan information, which includes the positions and number of glass substrates and is obtained through the scan task by the carrier slot scanning unit 135, to the manufacturing execution system 400.

The carrier unloading unit 137 may unload the carrier, for which transmission of the scan information has been completed by the slot information transmission unit 136, from the transfer equipment of the process equipment.

Meanwhile, the scan task execution unit 130 may sequentially perform scan tasks for all carriers included in the list generated by the list generation unit 110.

Next, the scan information comparison unit 140 may compare the scan information, which is transmitted to the manufacturing execution system 400 by the scan task execution unit 130, with slot information previously stored in the manufacturing execution system 400 and may determine whether the scan information matches the slot information.

To this end, as shown in FIG. 1, the scan information comparison unit 140 may include an information receiving unit 141, a position/quantity comparing unit 142, and a comparison result output unit 143.

The information receiving unit 141 may receive each piece of the scan information transmitted to the manufacturing execution system 400 and the slot information previously stored in the manufacturing execution system 400.

The position/quantity comparing unit 142 may compare the positions and number of glass substrates for the slots of the corresponding carrier according to the scan information received by the information receiving unit 141 with the positions and number of glass substrates for the slots of the corresponding carrier according to the slot information.

The comparison result output unit 143 may output a first result indicating a match or a second result indicating a mismatch, based on whether the positions and number of glass substrates match the slots of the corresponding carrier compared by the position/quantity comparing unit 142.

Next, the error occurrence notification unit 150 may be operated when the comparison result output by the scan information comparison unit 140 is the second result, and may stop the use of the carrier, store the carrier in the stocker, and transmit an error occurrence signal to the administrator terminal to notify the administrator of an error occurrence situation.

To this end, as shown in FIG. 1, the error occurrence notification unit 150 may include a first error determination unit 151, a second error determination unit 152, a carrier returning unit 153, a carrier storage unit 154, and an error information transmission unit 155.

The first error determination unit 151 may determine that an error has occurred during a process of allocating the carrier on a lot basis when the scan information does not match the slot information while the carrier is allocated on a lot basis and may output first error information accordingly.

The second error determination unit 152 may determine that an error has occurred in the carrier itself when the scan information does not match the slot information while the carrier is not allocated on a lot basis and may output second error information accordingly.

The carrier returning unit 153 may return, through the transport equipment, the carrier determined to have a first error or a second error by the first error determination unit 151 or the second error determination unit 152 to the stocker.

The carrier storage unit 154 may store the carrier returned by the carrier returning unit 153 in the stocker through a rack master.

The error information transmission unit 155 may transmit the first error information or second error information regarding the carrier, which is stored in the stocker by the carrier storage unit 154, to a terminal designated by the administrator to notify the administrator to correct the corresponding error.

Finally, when the scan tasks for all of the carriers included in the list performed by the scan task execution unit 130 are completed, the scan task termination unit 160 may release the scan task reserved in the process management server 300 to finish the scan task using the process equipment.

To this end, as shown in FIG. 1, the scan task termination unit 160 may include a scan task release unit 161 and a process equipment state restoring unit 162.

The scan task release unit 161 may release the scan task reserved in the process management server 300 when there is no carrier for which the scan task is not completed among the carriers included in the list.

The process equipment state restoring unit 162 may restore the process equipment that was changed to the in-use state for the scan task to the available state.

Then, since slot information for all the carriers stored in each stocker has been obtained, the scan task for the carriers may be completed. Thereafter, when a new carrier is stored in the stocker, a slot scan task for the corresponding carrier may be performed again.

According to the above configuration, an automatic carrier slot scanning apparatus for glass substrate semiconductor packages according to the embodiment automatically performs a slot scanning operation for checking the positions and number of glass substrates for each slot of a carrier stored in and unloaded from a stocker, thereby discovering slot errors of the carrier in advance, promptly notifying a manager thereof, allowing the manager to promptly respond to and correct the slot errors, and thus effectively preventing damage caused by the slot errors.

The above-described embodiments are merely exemplary, and various other embodiments modified therefrom may be implemented by those skilled in the art.

Accordingly, the true technical scope of the present invention should be construed as including not only the embodiments but also various other embodiments modified based on the technical spirit of the invention described in the following claims.

What is claimed is:

1. An automatic carrier slot scanning apparatus for glass substrate semiconductor packages, which scans positions and the number of glass substrates allocated on a lot basis for each slot of carriers that are handled in a glass substrate semiconductor package factory and each of which has an identification code attached thereto, and compares scanned information with slot information of a manufacturing execution system, the automatic carrier slot scanning apparatus comprising:
a list generation unit configured to generate a list of carriers stored in each stocker;
a scan task preparation unit configured to search for process equipment, which allows a scan task to be performed, and prepare the scan task;
a scan task execution unit configured to select any one carrier included in the list, load the selected carrier into the process equipment, and automatically scan the positions and the number of glass substrates for each slot of the carrier;
a scan information comparison unit configured to compare scan information, which is output according to the automatic scanning and corresponds to the positions and the number of glass substrates for the slots of the carrier, with slot information previously stored in the manufacturing execution system, and determine whether the scan information matches the slot information; and
an error occurrence notification unit configured to, when the scan information does not match the slot information based on a result of determining whether the scan information matches the slot information, set the carrier to a holding state, store the carrier in the stocker, and transmit an error occurrence signal to an administrator terminal.

2. The automatic carrier slot scanning apparatus of claim 1, wherein the scan task preparation unit includes:
a process equipment search unit configured to search for process equipment that is currently in an available state among a plurality of pieces of process equipment existing in the glass substrate semiconductor package factory;
a process equipment state change unit configured to change a state of the found process equipment from the available state to an in-use state; and
a scan task reservation unit configured to reserve a scan task in the manufacturing execution system so that the scan task is performed using the process equipment that is changed to the in-use state.

3. The automatic carrier slot scanning apparatus of claim 1, wherein the scan task execution unit includes:
a carrier selecting unit configured to select any one carrier included in the list;
a carrier discharge unit configured to discharge the selected carrier from the stocker through a rack master;
a carrier transport unit configured to transport the carrier discharged from the stocker to a sorter through transport equipment;
a carrier loading unit configured to load the carrier transported to the sorter into the process equipment;
a carrier slot scanning unit configured to scan the positions and the number of glass substrates for the slots of the carrier loaded into the process equipment;
a slot information transmission unit configured to transmit, to the manufacturing execution system, the scan information corresponding to the positions and the number of glass substrates for the slots of the scanned carrier; and
a carrier unloading unit configured to unload the scanned carrier from the process equipment.

4. The automatic carrier slot scanning apparatus of claim 1, wherein the scan information comparison unit includes:
an information receiving unit configured to receive each piece of the scan information and the slot information from the manufacturing execution system;
a position/quantity comparison unit configured to determine whether the positions and the number of glass substrates for the slots on the basis of the scan information match the positions and the number of glass substrates for the slots on the basis of the slot information; and
a comparison result output unit configured to output a comparison result according to whether the positions and the number of glass substrates for the slots on the basis of the scan information match the positions and the number of glass substrates for the slots on the basis of the slot information.

5. The automatic carrier slot scanning apparatus of claim 4, wherein the error occurrence notification unit includes:
a first error determination unit configured to, when the scan information and the slot information do not match each other based on the comparison result and the carrier is allocated on the lot basis, determine that an error occurs in a process of allocating the carrier on the lot basis and output first error information;
a second error determination unit configured to, when the scan information and the slot information do not match each other based on the comparison result and the carrier is not allocated on the lot basis, determine that an error occurs in the carrier itself and output second error information;
a carrier returning unit configured to return the carrier, which is determined to have the error by the first error determination unit and the second error determination unit, to the stocker through transport equipment;
a carrier storage unit configured to store the carrier, which is returned to the stocker, in the stocker through a rack master; and
an error information transmission unit configured to transmit the first error information or the second error information output by the first error determination unit or the second error determination unit to the administrator terminal to notify an administrator to correct the corresponding error.

6. The automatic carrier slot scanning apparatus of claim 3, further comprising a scan task termination unit configured to, when the scan task execution unit completes scan tasks for all the carriers included in the list, release the scan task reserved in a process management server so that the scan task using the process equipment is finished.
